(19) United States
(12) Patent Application Publication
(10) Pub. No.: US 2026/0054346 A1
(43) Pub. Date: Feb. 26, 2026

(54) HORIZONTAL NON-CONTACT CLEAN STATION FOR CHEMICAN MECHANICAL POLISHING CLEANER

(71) Applicant: Applied Materials, Inc., Santa Clara, CA (US)

(72) Inventors: John FOSTER, Santa Clara, CA (US); Johnathan LONG, Santa Clara, CA (US); Liam S. ROBERTS, Portland, OR (US)

(21) Appl. No.: 18/813,870

(22) Filed: Aug. 23, 2024

(51) Int. Cl. B24B 37/04; H01L 21/67

(52) U.S. Cl. CPC B24B 37/04; H01L 21/67051

(57) ABSTRACT

A noncontact cleaning module for a chemical mechanical polishing system is presented. The non-contact cleaning module comprises a vacuum table disposed within a processing area, a nozzle positioning arm disposed within the processing area and having a cleaning nozzle array configured to provide a cleaning fluid jet spray, and a rinse manifold having a center rinse bar and one or more spray bars.

### BACKGROUND

### Field

Embodiments described herein generally relate to equipment used in semiconductor manufacturing, and more particularly, to a non-contact clean module which may be used to clean the surface of a substrate in a semiconductor device manufacturing process.

### Description of the Related Art

Chemical mechanical polishing (CMP) is commonly used in the manufacturing of high-density semiconductor integrated circuits to planarize or polish a layer of material deposited on a substrate. In a typical CMP process, a substrate is retained in a carrier head that presses the backside of the substrate towards a rotating polishing pad in the presence of a polishing fluid. Material is removed across the material layer surface of the substrate in contact with the polishing pad through a combination of chemical and mechanical activity which is provided by the polishing fluid and a relative motion of the substrate and the polishing pad. Typically, after one or more CMP processes are complete a polished substrate is further processed to one or more post-CMP substrate processing operations. For example, the polished substrate may be further processed using one or a combination of cleaning, inspection, and measurement operations. Once the post-CMP operations are complete, a substrate can be sent out of a CMP processing area to the next device manufacturing process, such as a lithography, etch, or deposition process.

After polishing, the substrate is cleaned in a cleaning portion of the CMP system. Current cleaning process sequence after polishing processes includes loading a substrate into a contact clean module, such as a horizontal preclean module (HPC), soon after the substrate is transitioned to the cleaning portion of the CMP system. However, having a contact clean, e.g., an HPC with brushes, so soon after polishing, leads to increased contamination of the brushes in the module as the substrate is so loaded with polishing particles that the cleaning efficiency is significantly reduced. Additionally, these modules can apply a high shear force and high mechanical force during the cleaning process that can lead to surface damage, such as scratches, particularly on softer metal layers deposited on the substrate, such as copper layers.

Accordingly, there is a need for systems and apparatus to clean a substrate after chemical mechanical polishing that reduces the amount of surface damage caused to the substrate.

### SUMMARY

In one embodiment, a non-contact cleaning module comprises a vacuum table disposed within a processing area, a nozzle positioning arm disposed within the processing area and having a cleaning nozzle array configured to provide a cleaning fluid jet spray, and a rinse manifold having a center rinse bar and one or more spray bars.

In another embodiment, a chemical mechanical polishing (CMP) processing system comprises a polishing portion, and a transfer robot disposed between the polishing portion and a cleaning portion coupled to the polishing portion. The cleaning portion comprises a non-contact cleaning module disposed in the cleaning portion, a contact cleaning module disposed in the cleaning portion, and a substrate handler disposed between the non-contact cleaning module and the contact cleaning module. The CMP processing system further comprises a controller coupled to the CMP processing system and configured to cause the CMP processing system to polish a substrate in the substrate polishing portion, after polishing, place the substrate onto the non-contact cleaning module of the cleaning portion using the transfer robot, direct an energized cleaning fluid from a cleaning nozzle array of the non-contact cleaning module to a surface of the substrate, remove the substrate from the non-contact cleaning module using the substrate handler, and place the substrate in the contact cleaning module using the substrate handler.

In yet another embodiment, a method of processing a substrate comprises after polishing, placing a substrate into a non-contact cleaning module of a cleaning portion of a chemical mechanical polishing processing system, directing an energized cleaning fluid from a cleaning nozzle array of the non-contact cleaning module to a surface of the substrate, removing the substrate from the non-contact cleaning module, and placing the substrate in a contact cleaning module.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1A is a schematic plan view of an exemplary chemical mechanical polishing (CMP) processing system using a non-contact clean module, according to certain embodiments.

FIG. 1B is a top isometric view of an exemplary CMP processing system of FIG. 1A, according to certain embodiments.

FIG. 1C is a top elevation view of the CMP processing system of FIG. 1B, according to certain embodiments.

FIG. 2A is a top isometric view of a side of an exemplary non-contact clean module which may be used in a CMP processing system, according to certain embodiments.

FIG. 2B is another top isometric view of the side of the non-contact clean module of FIG. 2A, according to certain embodiments.

FIG. 2C is a top isometric view of a side of the non-contact clean module of FIG. 2A, according to certain embodiments.

FIG. 3 is a side sectional view of an exemplary cleaning nozzle positioning arm which may be used in the non-contact clean module of FIG. 2A, according to certain embodiments.

FIG. 4A depicts a plan view of the cleaning nozzle array of the nozzle which may be used in the non-contact clean module of FIG. 2A, according to certain embodiments.

FIG. 4B illustrates a simplified, schematic view of the cleaning nozzle array of FIG. 4A, according to certain embodiments.

FIG. 4C depicts a schematic side view of a spray pattern of a flat fan jet of the cleaning nozzle array of FIG. 4A, or a combination thereof, according to certain embodiments.

FIG. 5 illustrates a method of processing a substrate using a non-contact clean module in a cleaning portion of a CMP system, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to equipment used in the manufacturing of electronic devices, and more particularly, to a non-contact clean module which may be used to clean the surface of a substrate in a semiconductor device manufacturing process.

Contact cleaning modules, such as brush boxes and scrubbers, in cleaning process sequences for Chemical Mechanical Polishing (CMP) carry a risk of applying excessive mechanical force to the surface of the substrate. These modules can apply a high shear force and high mechanical force during the cleaning process, which is necessary to remove contamination from the substrate surface. However, the high shear force and high mechanical force can lead to surface damage, such as scratches, particularly on softer metal layers deposited on the substrate, such as copper layers. Further, systems with sequential brush boxes, such as a horizontal preclean module followed by a vertical preclean module, reduce processing time within each of the modules, while maintaining or even increasing the total scrubbing time. This increase in scrubbing time can lead to a higher cumulative mechanical force being applied to the substrate, increasing the risk of damage to the surface of the substrate.

Additionally, current cleaning sequence after polishing processes includes loading a substrate into a contact clean module, such as a horizontal preclean module (HPC), soon after the substrate is transitioned to the cleaning portion of the CMP system. The issue with having a contact clean, e.g., an HPC with brushes, so soon after polishing, however, is that the substrate is so loaded with particles that the brushes in the contact clean module, e.g., the HPC, become contaminated with the particles such that the cleaning efficiency is significantly reduced.

The present disclosure provides for an apparatus and systems for a non-contact clean module that includes nozzles to preclean a substrate after polishing. The systems provided incorporate the non-contact clean module as the initial module in the cleaning portion of the CMP system. This allows for contaminant particles to be removed from the substrate prior to contact clean modules, e.g., brush boxes, so as to improve the cleaning efficiency of the contact clean modules. Additionally, having a non-contact cleaning module as the initial module in a cleaning process sequence reduces the exposure of the substrate to excessive mechanical and shear forces, reducing surface damage on the substrate.

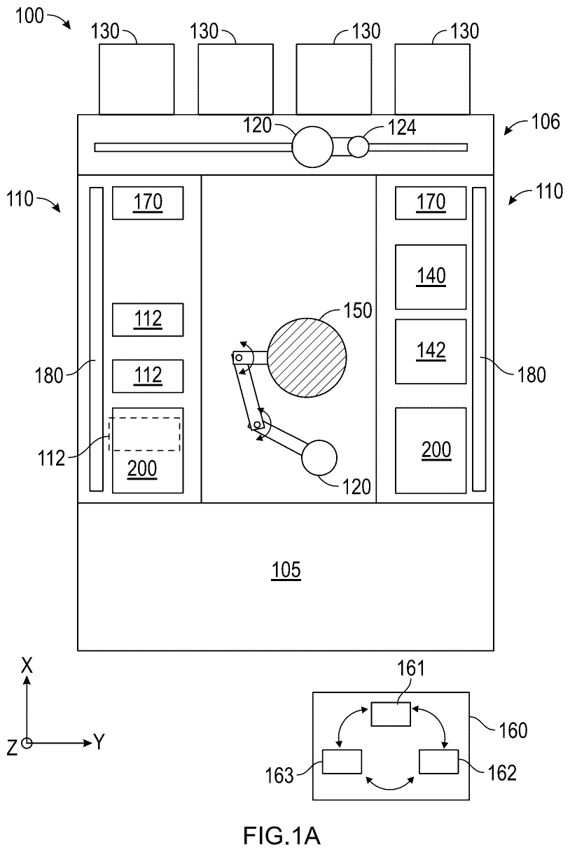

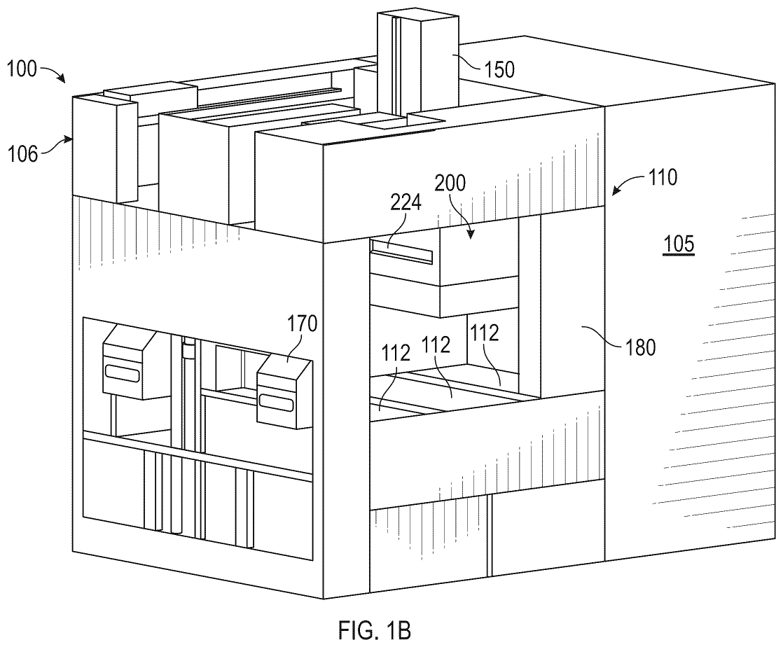

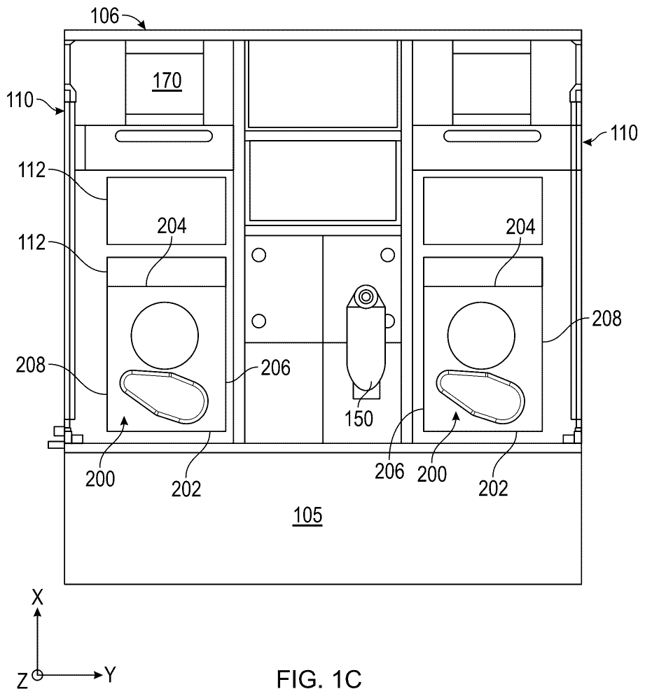

FIG. 1A is a schematic plan view of an exemplary chemical mechanical polishing (CMP) processing system 100, which uses a non-contact clean module described herein, according to one or more embodiments. FIG. 1B is a top isometric view of an exemplary CMP processing system 100 which may correspond to the schematic view shown in FIG. 1A, according to one or more embodiments. FIG. 1C is a top elevation view of the CMP processing system 100 of FIG. 1B which may correspond to the schematic view shown in FIG. 1A, according to one or more embodiments. In FIGS. 1B and 1C, certain parts of the housing and certain other internal and external components are omitted to more clearly show the non-contact clean module within the CMP processing system 100. Here, the CMP processing system 100 includes a first portion 105 and a second portion 106 coupled to the first portion 105 and integrated therewith. The first portion 105 is a substrate polishing portion featuring a plurality of polishing stations (not shown).

The second portion 106 includes one or more cleaning systems 110, a plurality of system loading stations 130, one or more substrate handlers, e.g., a first transfer robot 124 and a second transfer robot 150, one or more metrology stations 140, one or more location specific polishing (LSP) modules 142, one or more non-contact clean modules 200, and one or more drying units 170. The non-contact clean module 200 is configured to process a substrate 120 disposed in a substantially horizontal orientation (i.e., in the x-y plane). Alternatively, the non-contact clean module 200 may be configured to process a substrate 120 disposed in a substantially vertical orientation (i.e., in the y-z plane). In some embodiments, the second portion 106 optionally includes one or more contact cleaning modules 112 configured to process substrates 120 disposed in substantially vertical orientations (i.e., in the y-z plane).

Each LSP module 142 is typically configured to polish only a portion of a substrate surface using a polishing member (not shown) that has a surface area that is less than the surface area of a to-be polished substrate 120. LSP modules 142 are often used after the substrate 120 has been polished with a polishing module to touch up, e.g., remove additional material, from a relatively small portion of the substrate.

The metrology station 140 is used to measure the thickness of a material layer disposed on the substrate 120 before or after polishing, to inspect the substrate 120 after polishing to determine if a material layer has been cleared from the field surface thereof, and/or to inspect the substrate surface for defects before and/or after polishing. In those embodiments, the substrate 120 may be returned to the polishing pad for further polishing and/or directed to a different substrate processing module or station, such as a polishing module within the first portion 105 or to an LSP module 142 based on the measurement or surface inspection results obtained using the metrology station 140. As shown in FIG. 1A, a metrology station 140 and an LSP module 142 are located in a region of the second portion 106 that is above (in the Z-direction) portions of one of the cleaning systems 110.

The first transfer robot 124 is positioned to transfer substrates 120 to and from the plurality of system loading stations 130, e.g., between the plurality of system loading stations 130 and the second transfer robot 150 and/or between the cleaning system 110 and the plurality of system loading stations 130. In some embodiments, the first transfer robot 124 is positioned to transfer the substrate 120 between any of the system loading stations 130 and a processing system positioned proximate thereto. For example, in some embodiments, the first transfer robot 124 may be used to transfer the substrate 120 between one of the system loading stations 130 and the metrology station 140.

The second transfer robot 150 is used to transfer the substrate 120 between the first portion 105 and the second portion 106. For example, here the second transfer robot 150 is positioned to transfer a to-be-polished substrate 120 received from the first transfer robot 124 to the first portion 105 for polishing therein. The second transfer robot 150 is then used to transfer the polished substrate 120 from the first portion 105, e.g., from a transfer station (not shown) within the first portion 105, to one of the non-contact clean modules 200 and/or between different stations and modules located within the second portion 106. Alternatively, the second transfer robot 150 transfers the substrate 120 from the transfer station within the first portion 105 to one of the LSP modules 142 or the metrology station 140. The second transfer robot 150 may also transfer the substrate 120 from either of the LSP modules 142 or the metrology station 140 to the first portion 105 for further polishing therein.

The CMP processing system 100 in FIG. 1A features two cleaning systems 110 disposed on either side of the second transfer robot 150. In FIG. 1A at least some modules of one of the cleaning systems 110, e.g., one or more contact cleaning modules 112, such as a vertical cleaning module, are located below (in the z-direction) the metrology station 140 and the LSP module 142 and are thus not shown. The metrology station 140 and the LSP module 142 are not shown in FIG. 1C. In some other embodiments, the CMP processing system 100 features only one of the one or more cleaning systems 110. Here, each of the cleaning systems 110 includes a non-contact clean module 200, one or more contact cleaning modules 112 that may be a vertical cleaning module, e.g., brush or spray boxes, a drying unit 170, and a substrate handler 180 for transferring substrates 120 therebetween. Here, each non-contact clean module 200 is disposed within the second portion 106 in a location proximate to the first portion 105.

Typically, the non-contact clean module 200 receives a polished substrate 120 from the second transfer robot 150 through a first opening (not shown) formed in a side panel of the non-contact clean module 200, e.g., though a door or a slit valve disposed in the side panel. When the non-contact clean module 200 is horizontally oriented, the substrate 120 is received in a horizontal orientation by the non-contact clean module 200 for positioning on a horizontally disposed substrate support surface therein. The non-contact clean module 200 then performs a non-contact pre-clean process, such as a jet spray process, on the substrate 120 before the substrate 120 is transferred therefrom using a substrate handler 180.

The substrate 120 is transferred from the non-contact clean module 200 through a second opening, here a second substrate handler access door 224 (FIG. 1B), which is a horizontal slot disposed though a second side panel of the non-contact clean module 200 closeable with a door, e.g., a slit valve. Thus, the substrate 120 is still in a horizontal orientation as it is transferred from the non-contact clean module 200. After the substrate 120 is transferred from the non-contact clean module 200, the substrate handler 180 positions the substrate 120 to a vertical position for further processing in the contact cleaning modules 112 of the cleaning system 110. For example, the substrate handler 180 may swing the substrate 120 to the vertical position.

In this example, the non-contact clean module 200 has a first end 202 facing the first portion 105 of the CMP processing system 100, a second end 204 facing opposite the first end 202, a first side 206 facing the second transfer robot 150, and a second side facing opposite the first side 206. The first sides 206 and second sides 208 extend orthogonally between the first ends 202 and second ends 204.

The plurality of contact cleaning modules 112 are located within the second portion 106. The one or more contact cleaning modules 112 are any one or combination of contact cleaning systems for removing polishing byproducts from the surfaces of a substrate, e.g., spray boxes and/or brush boxes.

The drying unit 170 is used to dry the substrate 120 after the substrate has been processed by the cleaning modules 112 and before the substrate 120 is transferred to a system loading station 130 by the first transfer robot 124. Here, the drying unit 170 is a horizontal drying unit, such that the drying unit 170 is configured to receive a substrate 120 through an opening (not shown) while the substrate 120 is disposed in a horizontal orientation.

Herein, substrates 120 are moved between the non-contact clean module 200 and the contact cleaning modules 112, between individual ones of the cleaning modules 112, and between the cleaning modules 112 and the drying unit 170 using the substrate handler 180.

In embodiments herein, operation of the CMP processing system 100, including the substrate handler 180, is directed by a system controller 160. The system controller 160 includes a programmable central processing unit (CPU) 161 which is operable with a memory 162 (e.g., non-volatile memory) and support circuits 163. The support circuits 163 are conventionally coupled to the CPU 161 and comprise cache, clock circuits, input/output subsystems, power supplies, and the like, and combinations thereof coupled to the various components of the CMP processing system 100, to facilitate control thereof. The CPU 161 is one of any form of general purpose computer processor used in an industrial setting, such as a programmable logic controller (PLC), for controlling various components and sub-processors of the processing system. The memory 162, coupled to the CPU 161, is non-transitory and is typically one or more of readily available memories such as random access memory (RAM), read only memory (ROM), floppy disk drive, hard disk, or any other form of digital storage, local or remote.

Typically, the memory 162 is in the form of a non-transitory computer-readable storage media containing instructions (e.g., non-volatile memory), which when executed by the CPU 161, facilitates the operation of the CMP processing system 100. The instructions in the memory 162 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations. One or more system controllers 160 may be used with one or any combination of the various modular polishing systems described herein and/or with the individual polishing modules thereof.

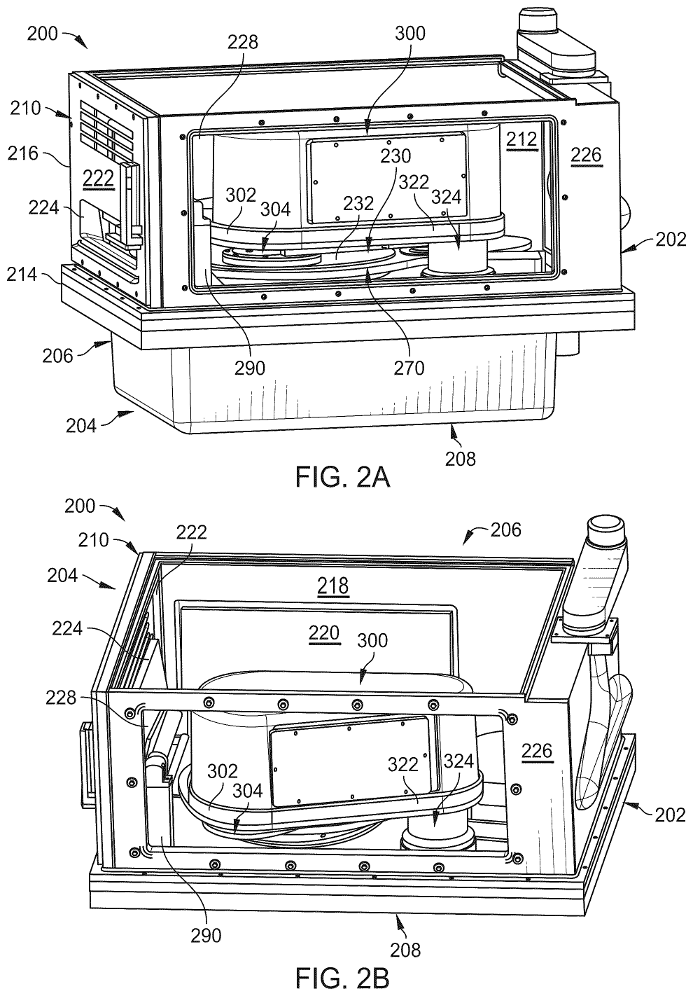

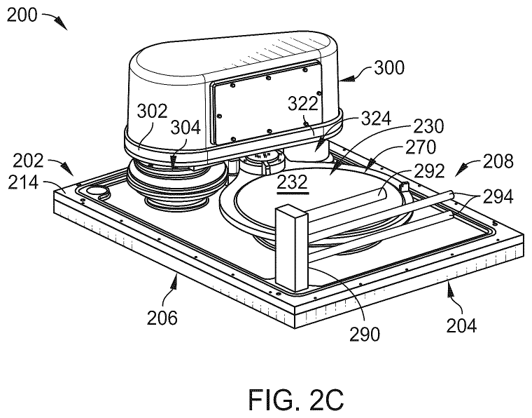

FIG. 2A is a top isometric view of a second side 208 of an exemplary non-contact clean module 200 which may be used in the CMP processing system 100 described herein. In FIG. 2A, a service access panel is omitted to more clearly show the internal components of the non-contact clean module 200. FIG. 2B is another top isometric view of the second side 208 of the non-contact clean module 200 of FIG. 2A. In FIG. 2B, a top panel of a lid 216 is further omitted to more clearly show the internal components of the non-contact clean module 200. FIG. 2C is a top isometric view of a first side 206 of the non-contact clean module 200 of FIG. 2A. In FIG. 2C, the lid 216 is omitted to more clearly show the internal components of the non-contact clean module 200.

Generally, the non-contact clean module 200 includes a chamber 210, here a basin 214 and a lid 216, formed of a plurality of side panels which collectively define a processing area 212.

A first side panel 218 is formed on the first side 206 of the non-contact clean module 200 facing the second transfer robot 150. The first side panel 218 includes a first substrate handler access door 220 used for positioning a substrate 120 on a vacuum table 230 with the second transfer robot 150. A second side panel 222 is disposed on the second end 204 of the non-contact clean module 200 facing away from the first portion 105. The second side panel 222 includes the second substrate handler access door 224 used for removing the substrate 120 from the vacuum table 230 with the substrate handler 180. A third side panel 226 is formed on the second side 208 of the non-contact clean module 200. The third side panel 226 includes a service access panel opening 228. The symmetry of the first substrate handler access door 220 and the service access panel opening 228 formed on opposite side panels of the non-contact clean module 200 beneficially provides a non-contact clean module that can be installed on either side of the CMP processing system 100 as illustrated in FIG. 1C.

The vacuum table 230 is disposed within the processing area 212 of the non-contact clean module 200 and may be used for vacuum chucking a substrate 120. Also disposed within the processing area 212 may be an annular substrate lift mechanism 270 disposed radially outward of the vacuum table 230, and a cleaning nozzle positioning arm 300 movable between a first position away from the vacuum table 230 and a second position over the vacuum table 230. For example, the cleaning nozzle positioning arm 300 may position the nozzle carrier assembly 304 over the first position disposed away from the supporting surface of the vacuum table 230 and over the second position disposed over the vacuum table 230.

The vacuum table 230, the annular substrate lift mechanism 270, and the cleaning nozzle positioning arm 300 are each independently mounted to the basin 214. The non-contact clean module 200 further includes a rinse manifold 290 mounted to the basin 214. A center rinse bar 292 and one or more spray bars 294 extend from a side of the rinse manifold 290. The center rinse bar 292 is used for directing a rinse fluid, e.g., a cleaning fluid or water, towards a center area of the vacuum table 230. The spray bars 294 are used for directing a spray towards one or more other areas of the vacuum table 230, e.g., a perimeter area or a side portion of the vacuum table 230. The rinse manifold 290 is positioned towards a corner of the basin 214, and the center rinse bar 292 and spray bars 294 extend along the second end 204 of the non-contact clean module 200 inside the second side panel 222. In some embodiments, the rinse manifold 290 is adjacent to the second side 208 (FIGS. 2A-2B). In some other embodiments, the rinse manifold 290 is adjacent to the first side 206 (FIG. 2C).

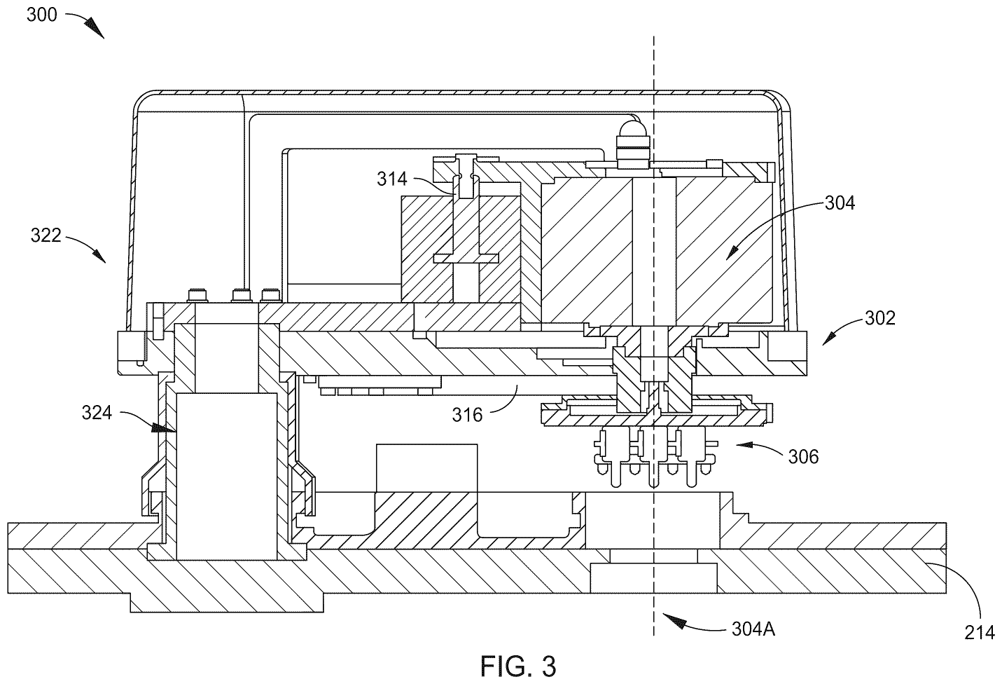

FIG. 3 is a side sectional view of an exemplary cleaning nozzle positioning arm 300 which may be used in the non-contact clean module 200 of FIG. 2A. The cleaning nozzle positioning arm 300 is disposed proximate to the vacuum table 230. A distal end 302 of the cleaning nozzle positioning arm 300 includes a vertically-movable nozzle carrier assembly 304 for supporting a cleaning nozzle array 306 at a lower end thereof.

After CMP, the non-contact clean module 200 is configured to clean away polishing slurry and debris before the substrate 120 dries. In some embodiments, the non-contact clean module 200 replaces one or more cleaning operations performed by the plurality of polishing stations of the first portion 105 of processing system 100

The cleaning nozzle positioning arm 300 includes a linear actuator 314, e.g., a pneumatic cylinder, coupled between the nozzle carrier assembly 304 and a proximal end 322 of the cleaning nozzle positioning arm 300. The linear actuator 314 is configured to raise and lower the nozzle carrier assembly 304 along an axis 304A for positioning the cleaning nozzle array 306 relative to a substrate 120 disposed on the vacuum table 230. In some embodiments, a pressure applied by the cleaning nozzle array 306 to the surface of the substrate 120 is about 0.5 psi or more, such as from about 0.5 psi to about 4 psi, such as about 3 psi, alternatively about 4 psi. An underside of the cleaning nozzle positioning arm 300 includes a chemistry manifold 316 having multiple spray nozzles to distribute chemistry, e.g., process fluids, onto the surface of the substrate 120.

The proximal end 322 of the cleaning nozzle positioning arm 300 is coupled to an actuator 324, e.g., a motor, configured to swing the nozzle carrier assembly 304 between the first position away from the vacuum table 230 and the second position over the vacuum table 230. The cleaning nozzle positioning arm 300 is configured to swing the nozzle carrier assembly 304 through the service access panel opening 228 to facilitate maintenance access thereto.

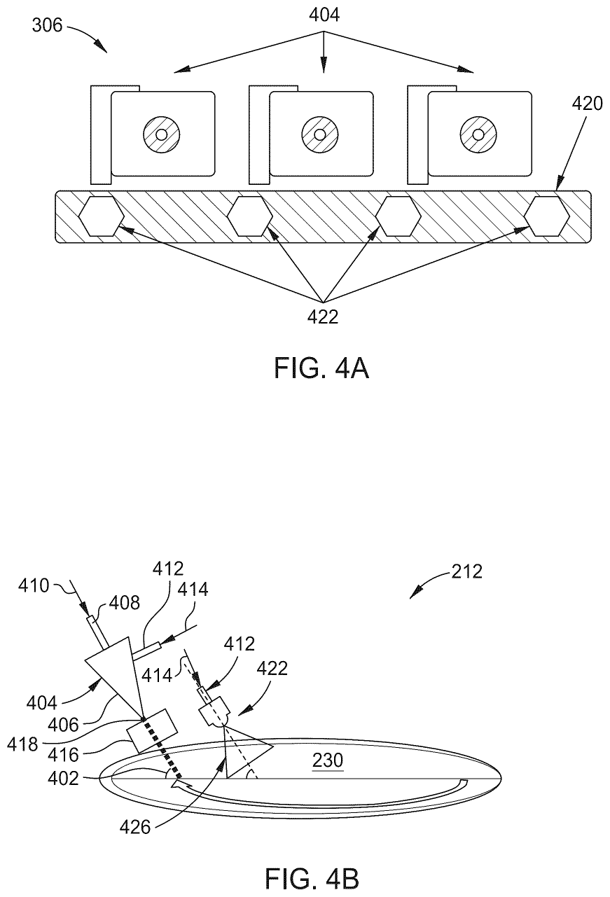

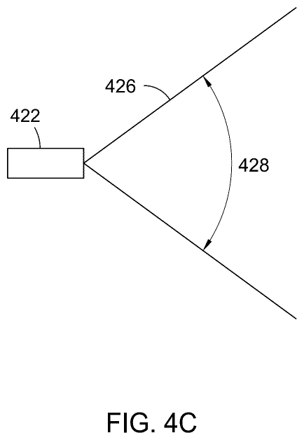

FIG. 4A depicts a schematic plan view of the cleaning nozzle array 306, according to certain embodiments. FIG. 4B illustrates a simplified, schematic view of the cleaning nozzle array 306 in the processing region 212, according to certain embodiments. As shown in FIG. 4A, the cleaning nozzle array 306 includes a plurality of outer cleaning nozzles 404, which spray a cleaning fluid jet onto an upper surface, an edge surface, a bevel surface, or a combination thereof, of a substrate, e.g., the substrate 120. As shown in FIG. 4B, the outer cleaning nozzles 404 (one shown) may be assisted jet nozzles such that an inert gas, e.g., nitrogen (N₂) or clean dry air (CDA), is supplied to increase the pressure of a cleaning fluid flow, which produces a cleaning fluid jet spray out of the nozzle. Each of the outer cleaning nozzles 404 includes a nozzle body 406 coupled to an inert gas supply 408 configured to flow an inert gas flow 410 at a gas pressure to the nozzle body 406 and to a cleaning fluid supply 412 configured to flow a cleaning fluid flow 414 to the nozzle body 406. The inert gas flow 410 and the cleaning fluid flow 414 merge in the nozzle body 406 to produce a cleaning fluid jet spray 416 at a jet spray pressure at a tip 418 of the nozzle body 406. The outer cleaning nozzles 404, along with the cleaning fluid jet spray, may be disposed at an angle 402 to the vacuum table 230. The angle 402 may be between about 0 degrees and about 180 degrees, such as between about 10 degrees and about 90 degrees, such as between about 30 degrees and 60 degrees.

The cleaning fluid jet spray may include deionized water (DIW), DIW and nitrogen, DIW and clean dry air (CDA), cleaning chemistry and nitrogen, cleaning chemistry and CDA, or combination(s) thereof. The cleaning fluid may be gas phase fluid and/or a mixed phase fluid, such as vapor and/or steam. The temperature of the cleaning fluid, such as steam is about 80° C. to about 150° C., such as about 100° C. to about 120° C., such as a temperature at or above a saturation temperature of the fluid. The pressure applied to energize the cleaning fluid, e.g., to create the cleaning fluid jet spray, is about 30 psi to about 140 psi, such as about 40 psi to about 50 psi. The cleaning fluid jet spray from the outer cleaning nozzles 404 applies enhanced pressure which, in combination with the cleaning chemistry of the cleaning fluid, is sufficient to dislodge contaminant particles from the surface of the substrate 120 without the use of mechanical force. This configuration allows for reduced surface damage, e.g., scratches, which would otherwise be caused by applying mechanical force, such as by brushes, providing a clean and defect-free substrate surface.

Referring to FIG. 4A, the cleaning nozzle array 306 also includes a nebulizer 420 having a plurality of flat fan nozzles 422 configured to spray cleaning fluids onto a substrate 120 (not shown in FIG. 4A) located radially adjacent the outer cleaning nozzles 404. The plurality of flat fan nozzles 422 rinse the substrate 120 with a cleaning fluid.

In some embodiments, the cleaning fluid is deionized water (DIW), DIW and nitrogen, DIW and clean dry air (CDA), cleaning chemistry and nitrogen, cleaning chemistry and CDA, or combination(s) thereof. The cleaning fluid is gas phase fluid and/or a mixed phase fluid, such as vapor and/or steam. The temperature of the cleaning fluid, such as steam is about 80° C. to about 150° C., such as about 100° C. to about 120° C., such as a temperature at or above a saturation temperature of the fluid. The pressure applied to energize the fluid is about 30 psi to about 140 psi, such as about 40 psi to about 50 psi.

To produce the cleaning fluid jet spray 416, the cleaning fluid flow 414 is energized. In some embodiments, the cleaning fluid flow 414 is energized by pressurizing a fluid, acoustically energized (e.g., via acoustic cavitation), pneumatically assisted (e.g., using liquid mixed with a pressured gas), or combination(s) thereof. Although the cleaning fluid jet spray 416 is shown to be configured to be energized using a pressurized inert gas flow 410 in FIGS. 4A-4C, other methods and combinations are also possible. For example, acoustic cavitation includes ultrasonically or megasonically energizing the fluid to dislodge residue and debris. Acoustically energizing fluid uses a piezoelectric transducer (PZT) operating in a frequency range from a lower ultrasonic range (e.g., about 20 KHz) to an upper megasonic range (e.g., about 2 MHz). Other frequency ranges can be used.

Each of the plurality of flat fan nozzles 422 are configured to direct fluid in a flat fan jet, e.g., flat fan jet 426 shown in FIGS. 4B-4C. FIG. 4C depicts a schematic side view of a spray pattern of a flat fan jet 426 for the plurality of flat fan nozzles 422. The flat fan jet is substantially parallel with a portion of an inner perimeter of the outer body 400 and a jet angle 428 pivoting at a tip of each of the plurality of flat fan nozzles 422 from a first edge to a second edge of the flat fan jet is about 30 degrees to about 50 degrees, such as about 40 degrees.

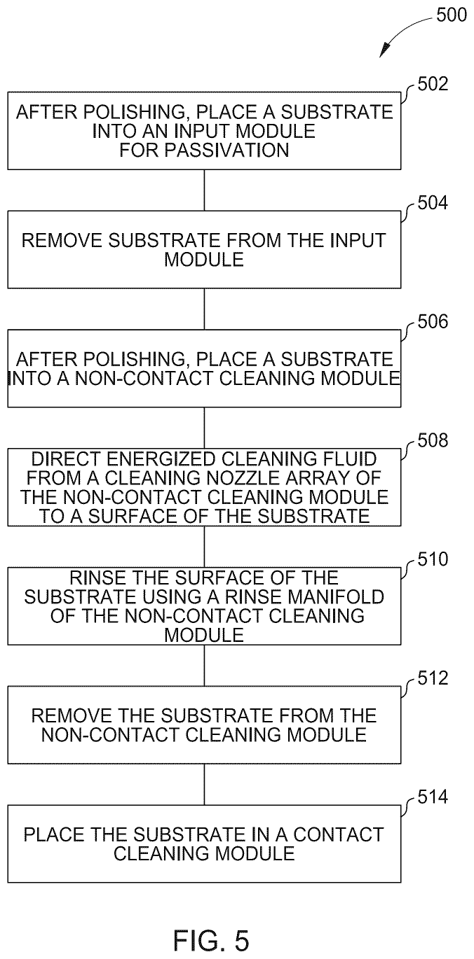

FIG. 5 illustrates a method of processing a substrate using a non-contact clean module, such as the non-contact clean module 200, in a cleaning portion, e.g., the second portion 106, of a CMP system, according to certain embodiments. The method 500 may begin with optional operation 502, where a substrate, e.g., substrate 120, is placed in an input module, e.g., a load cup, for processing. The load cup may passivate aspects of a surface of the substrate, but does not introduce cleaning processes. The substrate 120 is removed from the load cup after processing, e.g., by the second transfer robot 150, in operation 504.

In operation 506, the substrate is placed into the non-contact clean module 200 by the second transfer robot 150 as the initial module of the cleaning process sequence taking place in the cleaning portion of the system. For example, the second transfer robot 150 may place the substrate 120 into the non-contact clean module 200 by inserting the substrate 120 through first substrate handler access door 220 and positioning a substrate 120 on a vacuum table 230.

Once on the vacuum table 230, the substrate 120 may undergo a non-contact cleaning process in operation 508. The non-contact cleaning process includes directing energized cleaning fluid, e.g., the cleaning fluid jet spray 416, from a cleaning nozzle array 306 of the non-contact cleaning module 200 toward the surface of the substrate 120. For example, the cleaning nozzle array 306 may rotate from the first position, e.g., away from the vacuum table 230, to the second position, e.g., over the vacuum table 230, using the cleaning nozzle positioning arm 304. The cleaning nozzle array 306, which includes the outer cleaning nozzles 404 and the flat fan nozzles 422, then directs the outer cleaning nozzles 404 and the flat fan nozzles 422 toward a surface of the substrate 120 disposed on the vacuum table 230 such that cleaning delivered by the cleaning nozzle array 306, e.g., via the cleaning fluid jet spray 416, contacts the surface of the substrate 120. The cleaning fluid jet spray 416 may be delivered to the surface of the substrate 120 at a flow rate and pressure sufficient to cause particles or contaminants on the surface of the substrate 120 to be loosened or removed. In other words, the cleaning fluid jet spray exerts enough force to remove the particles without use of mechanical features, such as brushes. The cleaning nozzle array 306 may remain stationary once in a position over the vacuum table 230 or the cleaning nozzle array 306 may continually sweep across the surface of the substrate 120 to provide additional cleaning coverage of the surface of the substrate 120. Directing the cleaning fluid jet spray 416 to the surface of the substrate 120 also includes directing the cleaning nozzle array 306, e.g., the outer cleaning nozzles 404, to a bevel surface of the substrate 120 disposed on the vacuum table 230. This allows for the cleaning nozzle array 306 to clean the bevel surface or edge surface of the substrate 120.

The vacuum table 230 may also rotate, causing the substrate 120 to rotate, while the cleaning fluid flow is exerted on the substrate 120. The vacuum table 230 may rotate at speed of about 10 rpm to about 500 rpm, such as about 50 rpm to about 200 rpm.

Once the flow of the cleaning fluid ceases, the substrate 120 may be rinsed, e.g., using the center rinse bar 292 and the spray bars 294 of the rinse manifold, in operation 510 to remove any remaining cleaning fluid from the surface of the substrate prior to the substrate exiting the non-contact clean module 200.

Once the substrate is removed from the non-contact clean module 200 in operation 512, e.g., by the substrate handler 180, the substrate may be placed in a contact clean module, e.g., one of the one or more contact cleaning modules 112 to undergo a contact clean process in operation 514. For example, the substrate may undergo a vertical preclean process using a brush box. The brush box may include a pair of cylindrical rollers brushes. Each brush may further include a set of multiple raised nodules across the surface of the brush, and a set of multiple valleys located among the nodules. The pair of brushes may be supported by a pivotal mounting into and out of contact with the substrate 120 supported by a substrate support. The pair of brushes are actuated to rotate, applying a shear force, e.g., by scrubbing, to the surface of the substrate 120 while also applying a compressive mechanical force to remove contaminants.

The method 500 includes cleaning a substrate in a non-contact clean module as the first cleaning process after polishing. In contact clean modules, such as brush scrubbing modules, brushes are used to apply mechanical force on the surface of the substrate to facilitate dislodging contaminants from the substrate surface. Using this mechanical force as the initial cleaning process results in damage to the substrate surface, such as scratches, that deform the surface and produce defects. Additionally, the brushes become particularly contaminated with particles from substrate, such as residual polishing particles, and require frequent cleaning to maintain their cleaning efficiency. In contrast, using a non-contact clean module with assisted jet spray nozzles, as in method 500, allows for effective substrate surface cleaning while being gentle enough to prevent surface damage to the substrate.

The present disclosure provides for an apparatus and systems for a non-contact clean module that includes nozzles to preclean a substrate after polishing. The systems provided incorporate the non-contact clean module as the initial module in the cleaning portion of the CMP system to allow for contaminant particles to be removed from the substrate prior to contact clean modules, e.g., brush boxes, resulting in improved cleaning efficiency of the contact clean modules and reduced surface damage on the substrate.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another—even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A non-contact cleaning module, comprising:
a vacuum table disposed within a processing area;
a nozzle positioning arm disposed within the processing area and having a cleaning nozzle array configured to provide a cleaning fluid jet spray; and
a rinse manifold having a center rinse bar and one or more spray bars.

2. The non-contact cleaning module of claim 1, further comprising a controller coupled to the non-contact cleaning module and configured to cause the non-contact cleaning module to:
direct an energized cleaning fluid from the cleaning nozzle array of the non-contact cleaning module to a surface of a substrate positioned on the vacuum table.

3. The non-contact cleaning module of claim 1, wherein the cleaning nozzle array comprises outer cleaning nozzles configured to provide the cleaning fluid jet spray and a plurality of flat fan nozzles.

4. The non-contact cleaning module of claim 3, wherein each of the outer cleaning nozzles comprise a nozzle body to receive an inert gas flow at a gas pressure and to receive a cleaning fluid flow.

5. The non-contact cleaning module of claim 4, wherein the inert gas flow and the cleaning fluid flow merge in the nozzle body to produce a cleaning fluid jet spray at a jet spray pressure.

6. The non-contact cleaning module of claim 3, wherein the outer cleaning nozzles are disposed at an angle to the vacuum table of about 0 degrees and 180 degrees.

7. The non-contact cleaning module of claim 2, wherein the controller is further configured to:
after directing the energized cleaning fluid but before removing the substrate, rinse the substrate using the rinse manifold.

8. The non-contact cleaning module of claim 3, wherein directing the energized cleaning fluid to the surface of the substrate comprises directing the outer cleaning nozzles to a bevel surface of the substrate disposed on the vacuum table.

9. A chemical mechanical polishing (CMP) processing system, comprising:
a polishing portion;
a transfer robot disposed between the polishing portion and a cleaning portion coupled to the polishing portion, the cleaning portion comprising:
a non-contact cleaning module disposed in the cleaning portion;
a contact cleaning module disposed in the cleaning portion; and
a substrate handler disposed between the non-contact cleaning module and the contact cleaning module; and
a controller coupled to the CMP processing system and configured to cause the CMP processing system to:
polish a substrate in the substrate polishing portion;
after polishing, place the substrate onto the non-contact cleaning module of the cleaning portion using the transfer robot;
direct an energized cleaning fluid from a cleaning nozzle array of the non-contact cleaning module to a surface of the substrate;
remove the substrate from the non-contact cleaning module using the substrate handler; and
place the substrate in the contact cleaning module using the substrate handler.

10. The CMP processing system of claim 8, wherein the cleaning nozzle array comprises outer cleaning nozzles configured to provide a cleaning fluid jet spray and a plurality of flat fan nozzles.

11. The CMP processing system of claim 9, wherein each of the outer cleaning nozzles comprise a nozzle body coupled to an inert gas supply configured to flow an inert gas flow at a gas pressure to the nozzle body and to a cleaning fluid supply configured to flow a cleaning fluid flow to the nozzle body.

12. The CMP processing system of claim 10, wherein the inert gas flow and the cleaning fluid flow merge in the nozzle body to produce a cleaning fluid jet spray at a jet spray pressure.

13. The CMP processing system of claim 8, wherein the non-contact cleaning module further comprises a rinse manifold and wherein the controller is further configured to:
after directing the energized cleaning fluid but before removing the substrate, rinse the substrate using the rinse manifold.

14. The CMP processing system of claim 9, wherein directing the energized cleaning fluid to the surface of the substrate comprises directing the outer cleaning nozzles to a bevel surface of the substrate.

15. The CMP processing system of claim 8, wherein the non-contact clean module is configured to remove contaminant particles without using mechanical force.

16. A method of processing a substrate, comprising:
after polishing, placing a substrate into a non-contact cleaning module of a cleaning portion of a chemical mechanical polishing processing system;
directing an energized cleaning fluid from a cleaning nozzle array of the non-contact cleaning module to a surface of the substrate;
removing the substrate from the non-contact cleaning module; and
placing the substrate in a contact cleaning module.

17. The method of claim 16, further comprising:
after directing the energized cleaning fluid but before removing the substrate, rinsing the substrate using a rinse manifold of the non-contact cleaning module.

18. The method of claim 17, wherein the cleaning nozzle array comprises outer cleaning nozzles configured to provide a cleaning fluid jet spray and a plurality of flat fan nozzles.

19. The method of claim 18, wherein directing the energized cleaning fluid to the surface of the substrate comprises directing the outer cleaning nozzles to a bevel surface of the substrate.

20. The method of claim 18, wherein each of the outer cleaning nozzles comprise a nozzle body coupled to an inert gas supply configured to flow an inert gas flow at a gas pressure to the nozzle body and to a cleaning fluid supply configured to flow a cleaning fluid flow to the nozzle body.
